(19) United States
(12) Patent Application Publication
(10) Pub. No.: US 2025/0219616 A1
(43) Pub. Date: Jul. 3, 2025

(54) ETCHED REGION CONFIGURATIONS IN SOLIDLY-MOUNTED ACOUSTIC RESONATORS

(71) Applicant: Murata Manufacturing Co., Ltd., Nagaokakyo-shi (JP)

(72) Inventors: Bryant GARCIA, Mississauga (CA); Patrick TURNER, Portola Valley, CA (US); Greg DYER, Santa Barbara, CA (US); Naohiro NODAKE, Nagaokakyo-shi (JP); Albert CARDONA, Santa Barbara, CA (US); Takeshi NAKAO, Nagaokakyo-shi (JP); Drew MOROSIN, Oxnard, CA (US)

(21) Appl. No.: 18/987,949

(22) Filed: Dec. 19, 2024

Related U.S. Application Data
(60) Provisional application No. 63/616,220, filed on Dec. 29, 2023.

(51) Int. Cl. H03H 9/17; H03H 9/02; H03H 9/56

(52) U.S. Cl. CPC H03H 9/175; H03H 9/02228; H03H 9/568

(57) ABSTRACT

An acoustic resonator is provided that a substrate; a piezoelectric layer, a Bragg reflector layer disposed between the substrate and the piezoelectric layer, and an IDT at a surface of the piezoelectric layer that faces the Bragg reflector layer. The IDT includes a plurality of interleaved fingers extending from first and second busbars. Moreover, an etched region extends into at least a portion of the piezoelectric layer, the etched region including an area between the first busbar and a tip of at least one finger of the plurality of interleaved fingers extending from the second busbar in a first direction substantially parallel to a direction in which the interleaved fingers extend.

### CROSS REFERENCE TO RELATED APPLICATIONS

The current application claims priority to U.S. Patent Provisional Application No. 63/616,220, filed Dec. 29, 2023, the entire contents of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

### SUMMARY

As noted above, resonator performance improvements, such as an improved Q factor, also have an improvement effect on the RF filters and network devices that include the improved resonator. As further described herein, an etched region of the piezoelectric layer located near or at the interdigital transducer (IDT)-busbar area (BE Gap) is used in a resonator structure to improve Q factor of the resonator. Structures in the BE Gap generally affect acoustic leakage and mode suppression and the etched region structure described herein achieves an improved Q factor by reducing acoustic leakage in the BE Gap. Additionally, fabrication of the described etched region and improvement of the Q factor as described herein may be achieved without etching through the metal layer of the IDT. Accordingly, Q factor of resonator devices may be improved by using the described etched region without affecting the metal layer of the IDT.

In an exemplary aspect, an acoustic resonator is provided that includes a substrate; a piezoelectric layer; a Bragg reflector layer disposed between the substrate and the piezoelectric layer; and an interdigital transducer (IDT) at a surface of the piezoelectric layer that faces the Bragg reflector layer, the IDT including a plurality of interleaved fingers extending from a first busbar and a second busbar. Moreover, at least one etched region extends into at least a portion of the piezoelectric layer, the at least one etched region including an area between the first busbar and a tip of at least one finger of the plurality of interleaved fingers extending from the second busbar.

In another exemplary aspect of the acoustic resonator, two adjacent fingers of the plurality of interleaved fingers extend from the first direction and the at least one etched region is located between the two adjacent fingers relative to a direction that is substantially perpendicular to a direction in which the fingers extend.

In another exemplary aspect of the acoustic resonator, the at least one etched region comprises a plurality of first etched regions, each of the plurality of etched regions being located (i) between a different set of adjacent fingers extending from the first busbar, and (ii) between the first busbar and a tip of a corresponding finger of the plurality of interleaved fingers extending from the second busbar.

In another exemplary aspect, the acoustic resonator further comprises a plurality of second etched regions extending in at least a portion of the piezoelectric layer, each of the plurality of second etched regions being located (i) between the second busbar and a tip of a corresponding finger of the plurality of interleaved fingers extending from the first busbar, and (ii) between a different set of adjacent fingers extending from the second busbar.

In another exemplary aspect of the acoustic resonator, the at least one etched region includes a first trench extending in a direction substantially perpendicular to a direction in which the plurality of interleaved fingers of the IDT extend, the first trench being located between the first busbar and tips of the plurality of interleaved fingers extending from the second busbar and being disposed over the plurality of interleaved fingers extending from the first busbar.

In another exemplary aspect of the acoustic resonator, the at least one etched region includes a second trench extending in the direction substantially perpendicular to the direction in which the plurality of interleaved fingers of the IDT extend, the second trench being located between the second busbar and tips of the plurality of interleaved fingers extending from the first busbar and being disposed over the plurality of interleaved fingers extending from the second busbar.

In another exemplary aspect of the acoustic resonator, the first trench and the second trench extend partially into the piezoelectric layer in a thickness direction measured substantially perpendicular to a surface of the piezoelectric layer, such that a thickness of the piezoelectric layer is smaller in the first trench and the second trench than a thickness of the piezoelectric layer outside of the first trench and the second trench.

In another exemplary aspect of the acoustic resonator, the first trench and the second trench are connected to each other by two connecting trenches extending, such that the plurality of interleaved fingers of the IDT are disposed between the two connecting trenches in a plan view of the piezoelectric layer.

In another exemplary aspect of the acoustic resonator, the at least one etched region is directly adjacent to the first busbar, such that the first busbar defines a sidewall of the at least one etched region.

In another exemplary aspect of the acoustic resonator, the at least one etched region extends partially into the piezoelectric layer in a thickness direction measured substantially perpendicular to a surface of the piezoelectric layer, such that a thickness of the piezoelectric layer is smaller in the at least one etched region than a thickness of the piezoelectric layer outside of the at least one etched region.

In another exemplary aspect of the acoustic resonator, the at least one etched region extends fully through the piezoelectric layer.

In another exemplary aspect of the acoustic resonator, the Bragg reflector layer is partially removed in the at least one etched region, such that a thickness of the Bragg reflector layer is smaller in the at least one etched region than a thickness of the Bragg reflector layer outside of the at least one etched region.

In another exemplary aspect of the acoustic resonator, a distance D1 between the tip of the at least one finger and an edge of the at least one etched region that is adjacent to the tip is less than a distance D2 between a side surface of the first busbar and an edge of the at least one etched region that is adjacent to the first busbar, the distances D1 and D2 being measured in a direction parallel to a plan view of the piezoelectric layer.

In another exemplary aspect, a filter device is provided that includes a plurality of bulk acoustic resonators each including a substrate; a piezoelectric layer; at least one Bragg reflector layer disposed between the substrate and the piezoelectric layer; and an interdigital transducer (IDT) at a surface of the piezoelectric layer, the IDT including a plurality of interleaved fingers extending from first and second busbars. In this aspect, at least one bulk acoustic resonator of the plurality of bulk acoustic resonators includes at least one etched region where a portion of the piezoelectric layer is removed. Moreover, the at least one etched region includes an area between a first busbar of the IDT and a tip of at least one finger of the plurality of interleaved fingers.

In another exemplary aspect, a radio frequency module is provided that includes a filter device including a plurality of bulk acoustic resonators; and a radio frequency circuit coupled to the filter device, the filter device and the radio frequency circuit being enclosed within a common package. In this aspect, at least one of the plurality of bulk acoustic resonators of the filter device includes a substrate; a piezoelectric layer; at least one Bragg reflector layer disposed between the substrate and the piezoelectric layer; and an interdigital transducer (IDT) at a surface of the piezoelectric layer, the IDT including a plurality of interleaved fingers extending from first and second busbars. Moreover, at least one bulk acoustic resonator of the plurality of bulk acoustic resonators includes at least one etched region where a portion of the piezoelectric layer is removed, the at least one etched region including an area between a first busbar of the IDT and a tip of at least one finger of the plurality of interleaved fingers that extends from a second busbar of the IDT.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1 includes a schematic plan view and two schematic cross-sectional views of a transversely-excited film bulk acoustic resonator (XBAR).

FIG. 2A is an expanded schematic cross-sectional view of a portion of the XBAR of FIG. 1.

FIG. 2B is an expanded schematic cross-sectional view of an alternative configuration of the XBAR of FIG. 1.

FIG. 2C is an expanded schematic cross-sectional view of another alternative configuration of the XBAR of FIG. 1.

FIG. 2D is an expanded schematic cross-sectional view of another alternative configuration of the XBAR of FIG. 1.

FIG. 3 is an expanded schematic cross-sectional view of a portion of a solidly-mounted XBAR (SM XBAR).

FIG. 4 is a graphic illustrating a shear horizontal acoustic mode in an XBAR.

FIG. 5A is a schematic block diagram of a filter using XBAR of FIG. 1.

FIG. 5B is a schematic diagram of a radio frequency module that includes an acoustic wave filter device according to an exemplary aspect.

FIG. 6A is a plan view of an SM XBAR having plural etched regions according to an exemplary aspect.

FIG. 6B is a cross-sectional view showing one of the etched regions of FIG. 6A according to an exemplary aspect.

FIG. 7A is a plan view of an SM XBAR having a trench etched region according to an exemplary aspect.

FIGS. 7B and 7C show cross-sectional views illustrating the trench etched regions of FIG. 7A according to an exemplary aspect.

FIG. 8A is a plan view of an SM XBAR having a trench etched region adjacent to a busbar according to an exemplary aspect.

FIGS. 8B and 8C show cross-sectional views illustrating the trench etched regions of FIG. 8A according to an exemplary aspect.

FIG. 9 is a plan view of an SM XBAR having connected trench etched regions according to an exemplary aspect.

FIG. 10 illustrates a flowchart of a method of manufacturing a filter as described herein according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

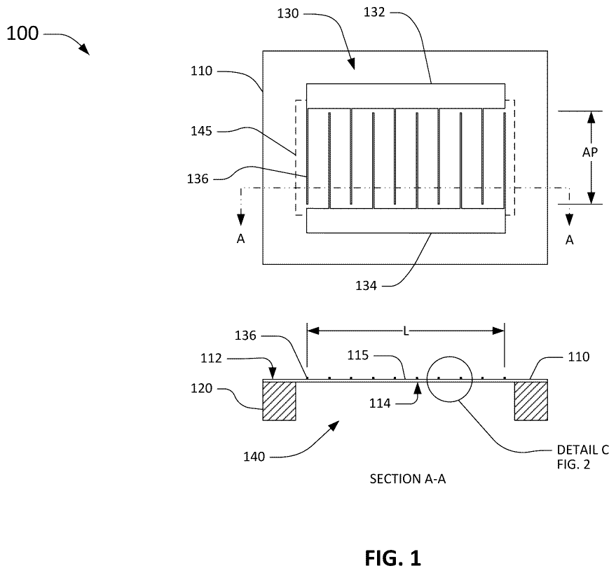

FIG. 1 shows a simplified schematic top view and orthogonal cross-sectional views of an acoustic resonator device, namely a transversely excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120−90.0) and (0, 128−90.0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer, or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

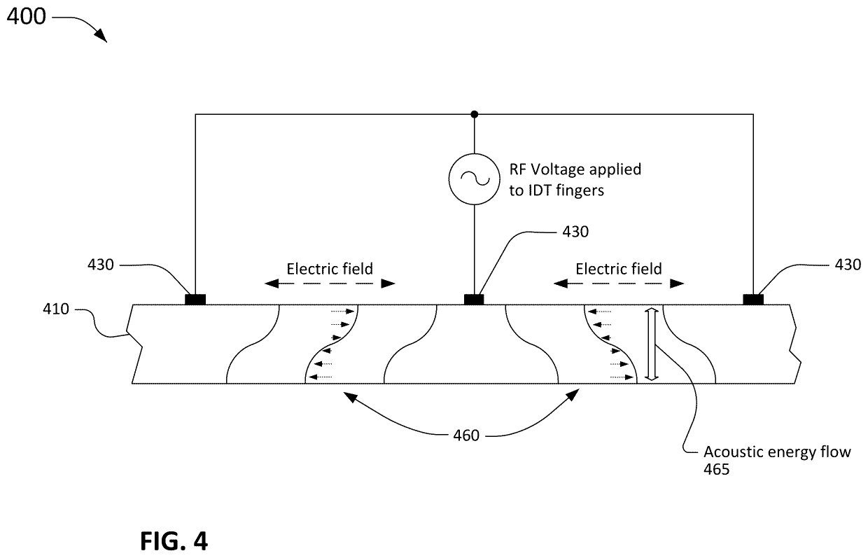

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, thereby adjusting the overall capacitance of the XBAR 100.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

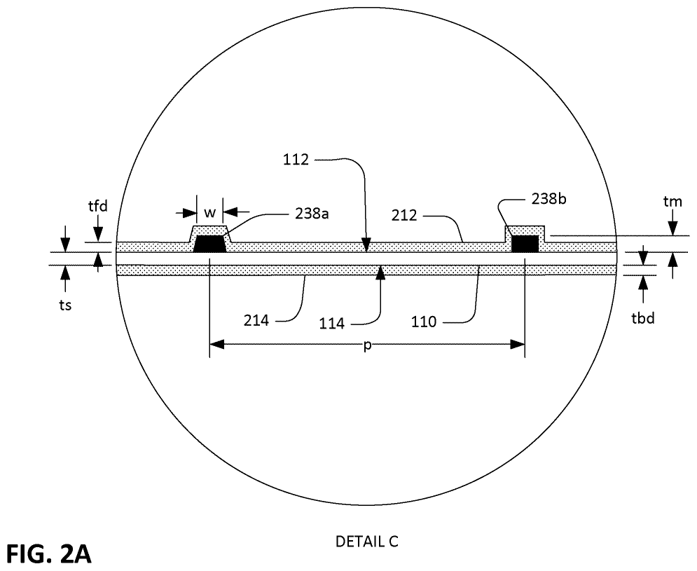

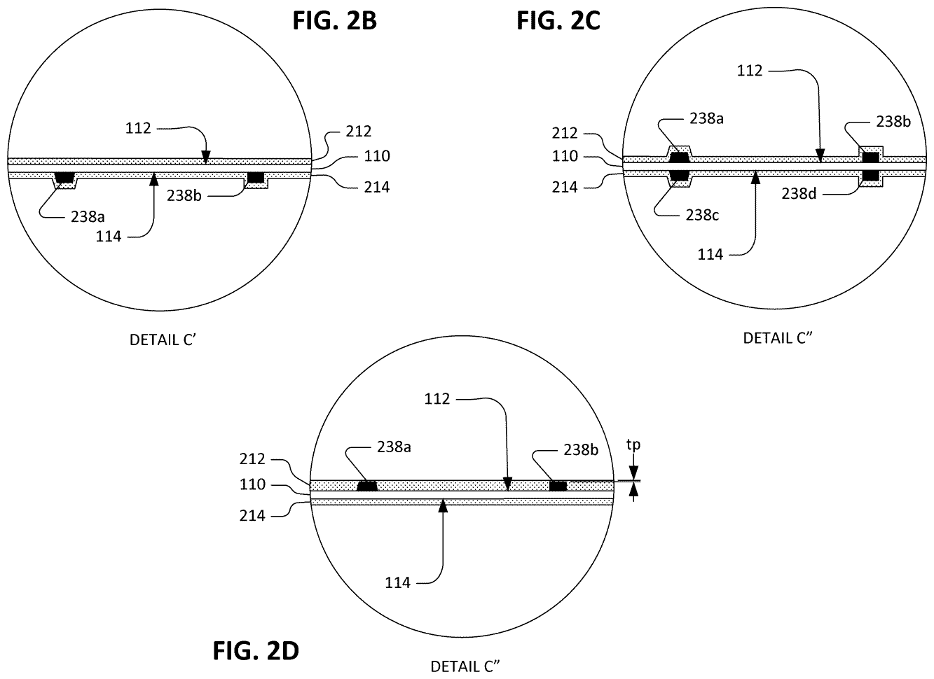

FIG. 2A shows a detailed schematic cross-sectional view of the XBAR 100 of FIG. 1. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially aluminum alloys, copper, substantially copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1.

In general, the IDT of an XBAR differs substantially from the IDTs used in surface acoustic wave (SAW) resonators, primarily in that IDTs of an XBAR excite a shear thickness mode, as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the acoustic resonator can be solidly mounted in which the diaphragm with IDT fingers is mounted on or above an acoustic mirror, such as a Bragg mirror or Bragg stack, which in turn can be mounted on a substrate.

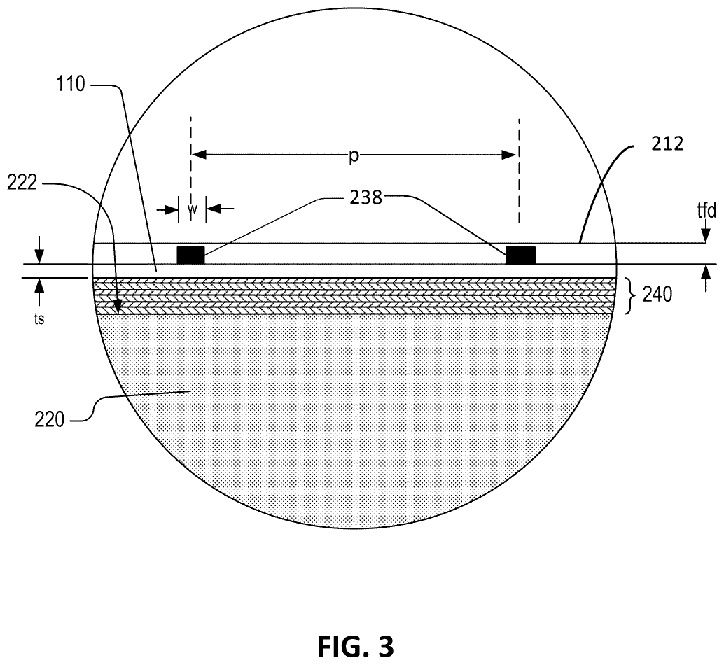

In particular, FIG. 3 shows a detailed schematic cross-sectional view of a solidly mounted XBAR (SM XBAR). The SM XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p. It should be appreciated that the pair of IDT fingers 238 are interleaved fingers of an IDT having a plurality of interleaved fingers as described above.

In contrast to the XBAR devices shown in FIG. 1, the IDT of an SM XBAR in FIG. 3 is not formed on a diaphragm spanning a cavity in the substrate. Instead, an acoustic Bragg reflector 240 (also referred to as a Bragg mirror or Bragg stack) is sandwiched between a surface 222 of the substrate 220 and the back surface of the piezoelectric layer 110. The term “sandwiched” means the layers of the acoustic Bragg reflector 240 are both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 3, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer. Moreover, in another exemplary aspect as discussed below, the conductor pattern, which includes the IDT, can be disposed between the piezoelectric layer and the Bragg reflector 240.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D and FIG. 3 according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

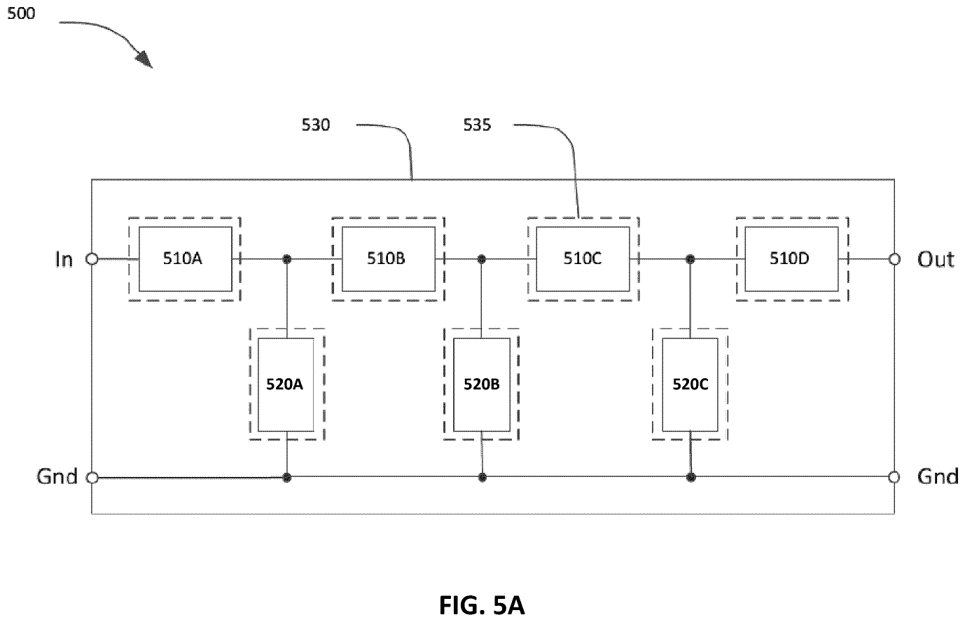

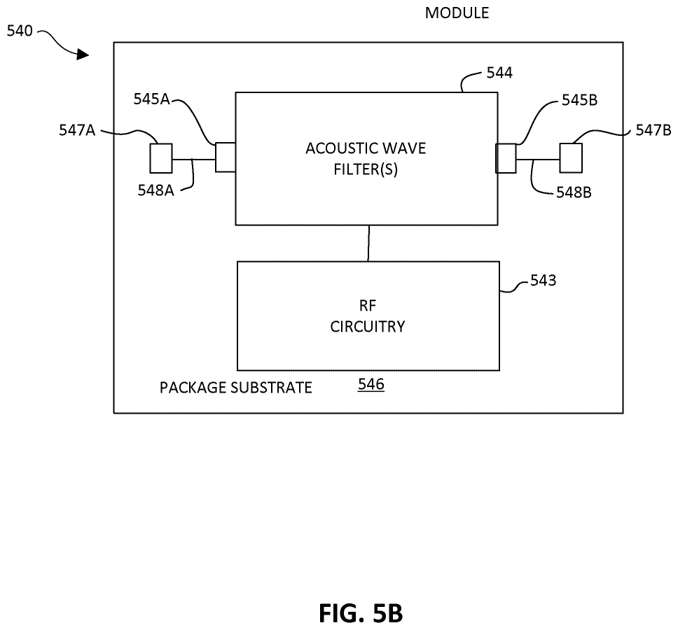

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least three shunt resonators, such as the shunt resonators 520A-520C, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 3), which in turn can be mounted on a substrate. In this case, the cavities (e.g., identified as rectangles 535) would be omitted. Instead, one or more Bragg mirrors can be disposed one, some or all of the resonators of the ladder filter.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

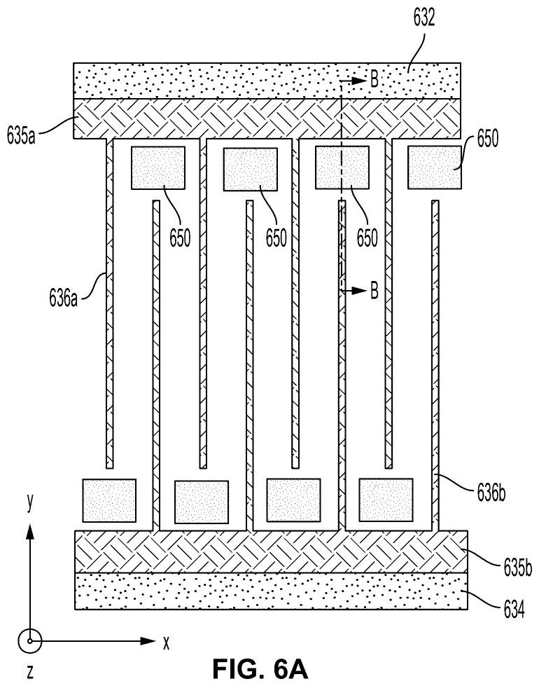

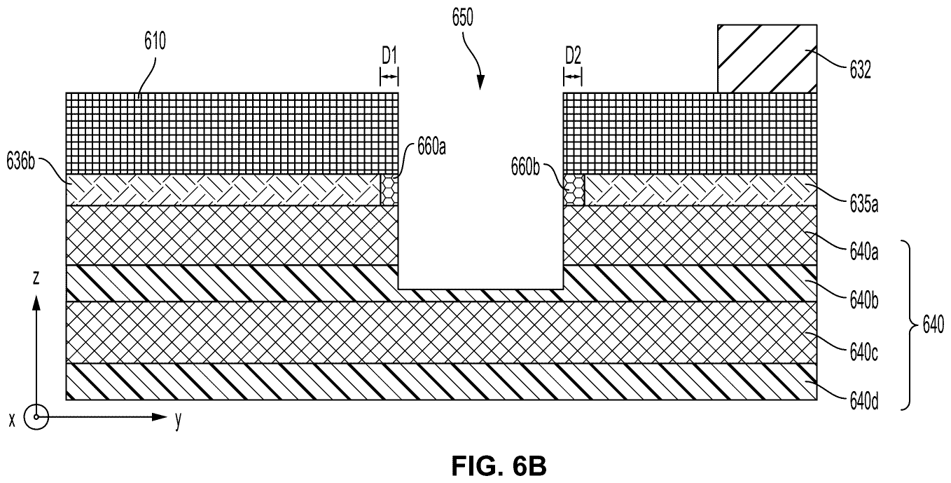

According to an exemplary aspect, an RF filter device, such as filter 500 described above with respect to FIG. 5A or the acoustic wave filters 544 described above with respect to FIG. 5B, can be configured to include SM XBARs having an etched region where at least a part of the piezoelectric layer is removed to improve the Q factor of the SM XBARs by reducing acoustic leakage, thereby improving filter performance. Each of the exemplary embodiment described below with reference to FIGS. 6A-6B, 7A-7C, 8A-8C and 9 illustrate an exemplary embodiment in which at least one etched region and often a plurality of etched regions are disposed between respective tips of the interleaved fingers and the busbar facing the tips of the interleaved fingers. As will be described in more detail below, the at least one etched region extends partially into the piezoelectric layer and/or completely through the piezoelectric layer and into the Bragg stack below the conductor pattern to improve the Q factor of the acoustic resonator.

For purposes of the exemplary embodiment described below with reference to FIGS. 6A-6B, 7A-7C, 8A-8C and 9, each acoustic resonator is shown with respect to X, Y and Z axes. The X-Y plane generally defines a plane that is substantially parallel to a first surface of the piezoelectric layer as described herein. The Z axis extends in the vertical or thickness direction of the acoustic resonators. Moreover, the Y axis is considered a “first direction” for purposes of this disclosure, the X axis is considered a “second direction” for purposes of this disclosure, and the Z axis is considered a “third direction” for purposes of this disclosure.

In this regard, FIG. 6A illustrates an exemplary aspect of including at least one etched region, and in the particular aspect, a plurality of etched regions in the BE Gap (i.e., in the area near or at the interdigital transducer (IDT)-busbar region). It should be appreciated that the acoustic wave filters 500 of FIG. 5A may be configured to include SM XBARs having one or more etched regions in the BE Gap.

As illustrated, FIG. 6A shows a plan (i.e., top-down) view of an SM XBAR having a plurality of etched regions 650. In an exemplary aspect, the SM XBARs described herein with respect to FIGS. 6-8 may have a structure similar to the SM XBAR discussed above with respect to FIG. 3, with the modification that the conductor pattern forming the IDT (e.g., the interleaved fingers 238 in FIG. 3) is located on a side of the piezoelectric layer that faces the substrate (220 in FIG. 3). That is, the SM XBARs described with reference to FIGS. 6-8 include a conductor pattern that is located between (e.g., sandwiched between) at least one layer of the Bragg stack (also referred to as Bragg reflector or Bragg mirror) and the piezoelectric layer. One or more additional dielectric layers (not shown) may also be disposed between the Bragg stack and the piezoelectric layer, for example, between the conductor pattern and the piezoelectric layer or between the conductor pattern and the Bragg stack.

The outermost (top and bottom) layers shown in FIG. 6A represent metal layers forming the busbars and to which the interleaved fingers of the IDT are connected. In particular, a conductor pattern as described above includes first metal layers 635a and 635b, which can be considered part of the busbars or separate metal layers. The first and second busbars are generally considered to be extending in a first direction in an exemplary aspect. Moreover, a first plurality of fingers 636a extend in a second direction (e.g., substantially perpendicularly to the first direction) from metal layer 635a and a second plurality of fingers 636b extend in the second direction from metal layer 635b. These interleaved fingers 636a and 636b can generally correspond to fingers 136 of FIG. 1 and/or fingers 238 of FIG. 3 for the SM-XBAR. Moreover, second metal layers 632 and 634 are electrically coupled to first metal layers 635a and 635b, respectively, by one or more electrically conductive vias (not shown), for example.

In an exemplary aspect, first metal layer 635a and second metal layer 632 can collectively be considered to form a busbar, such as busbar 132 of FIG. 1. Similarly, second metal layer 635b and second metal layer 634 can collectively be considered to form a busbar, such as 134 of FIG. 1. As will be described with respect to FIG. 6B a piezoelectric layer 610 is disposed on at least the conductor pattern that forms the interleaved fingers 636a and 636b and metal layers 635a and 635b (or a portion thereof), such that the conductor pattern is between the piezoelectric layer 610 and a Bragg stack 640. It is noted that the piezoelectric layer 610 is not shown in the plan view of FIG. 6A in order to illustrate the positions of the etched regions 650 with respect to the metal layers 635a and 635b of the conductor pattern, which is below the piezoelectric layer 610.

The etched regions 650 are delineated in FIG. 6A as rectangular areas near the tips of each of the fingers 636a and 636b of the IDT, for example, in the BE gaps that are between the tips of the IDT interleaved fingers and the busbar, which includes metal layers 635a and 635b. As noted above, first metal layers 635a and second metal layer 632 can collectively be considered a first busbar of the acoustic resonator and first metal layers 635b and second metal layer 634 can collectively be considered a second busbar of the acoustic resonator. It is also noted that the etched regions 650 are not limited to a rectangular shape and may be any suitable shape. In the exemplary aspect of FIG. 6A, each of the etched regions 650 in a top row (e.g., plurality of first etched regions 650) is located between the top busbar (e.g., first metal layer 635a and second metal layer 632) and the tip of a finger (e.g., finger 636b) extending from the bottom busbar, in a vertical direction (e.g., the Y axis or first direction). Likewise, each of the etched regions 650 in a bottom row (e.g., plurality of second etched regions 650) is located between the bottom busbar (e.g., metal layer 635b and metal layer 634) and the tip of a finger (e.g., finger 636a) extending from the top busbar, in the vertical direction (e.g., the Y axis or first direction). As shown, each of the etched regions 650 is located between two adjacent fingers (in the second direction, which is the X axis direction) extending from each respective busbar.

In other words, the etched regions 650 extend into at least a portion of the piezoelectric layer 610 and include an area between the respective busbars and tips of the interleaved fingers extending from the second busbar in the first direction substantially parallel with a direction in which the interleaved fingers extend (e.g., the Y axis direction). In this aspect, the first and second busbars may extend substantially parallel to each other and in a second direction (e.g., the X axis direction). Thus, the interleaved fingers extend substantially orthogonally from the busbars. It should be appreciated that for purposes of this disclosure, the term “substantially” or “substantially orthogonal” or “substantially parallel”, takes into account manufacturing variances and that the angles can accounting for a small tolerance, such as +5° or −5°.

Additionally, as shown in the exemplary aspect of FIG. 6A, each etched region 650 in the top row is located between a different set of adjacent fingers 636a extending from the top busbar, in a horizontal or lengthwise direction (e.g., the second direction). Each etched region 650 in the bottom row of FIG. 6A is located between a different set of adjacent fingers 636b extending from the bottom busbar, in a horizontal or lengthwise direction (e.g., the second direction). It is noted that while the exemplary aspect of FIG. 6A shows an etched region 650 between each set of adjacent fingers, the number of etched regions is not limited to the exemplary configuration of FIG. 6A. More or fewer etched regions may be included in the SM XBAR in other aspects.

FIG. 6B shows a cross-sectional view of the area denoted with a dashed line (i.e., Section B-B) in FIG. 6A, which passes through one of the etched regions 650. As shown in the cross-section view of FIG. 6B, the piezoelectric layer 610 covers the conductor pattern of the IDT in this exemplary aspect, such that the IDT is at the surface of the piezoelectric layer 610 that faces downward toward the Bragg stack 640 and the substrate (under the Bragg stack 640). While the substrate is not shown in the cross-sectional view of FIG. 6B, the substrate is understood to support (or partially support) the Bragg stack, as shown in FIG. 3. Furthermore, the full Bragg stack 640 may not be shown in FIG. 6B, which shown only four alternating layers 640a, 640b, 640c and 640d. The Bragg stack 640 may include more or fewer layers (e.g., layers 640a to 640d) in alternative aspects. In an alternative aspect, the conductor pattern could be disposed on the top surface of the piezoelectric layer.

The etched region 650 shown in FIG. 6B shows full removal of the piezoelectric layer 610 and partial removal (e.g., one or more layers 640a and 640b) of the Bragg stack 640, such that a thickness of the Bragg stack is smaller in the etched region 650 than a thickness of the Bragg stack 640 outside of the etched region. As further shown, the etched region is positioned in an area where there is no IDT metal layer. The first metal layer 635a forming the first busbar is to the right of the etched region 650 in FIG. 6B. Moreover, the tip of one of fingers 636b is shown to the left of the etched region 650. Accordingly, the etched region passes through the spacer at the IDT metal layer (i.e., in the BE gap). The positioning of the etched regions 650 in the exemplary aspect of FIGS. 6A and 6B is advantageous because etching the conductor pattern forming the IDT layer is avoided, no matter the depth of the etched region.

In an exemplary aspect, a filler material 660a and/or 660b is provided between the piezoelectric layer 610 and the top layer 640a of Bragg stack 640. This filler material 660a and/or 660b may correspond to a dielectric layer (e.g., a silicon oxide), such as dielectric layer 212 of FIG. 3, which is disposed on the conductor pattern for example. As shown in FIG. 6B, the etched region 650 extends through the dielectric layer leaving filler material 660a and/or 660b on each side of the conductor pattern.

Moreover, according to the exemplary aspect, a distance D1 in the Y axis direction (i.e., a direction that is parallel to the plan view of the piezoelectric layer) from the end or side surface of IDT finger 636b to the end (or perimeter) of the etched region 650 is less than a distance D2 in the Y axis direction (i.e., a direction that is parallel to the plan view of the piezoelectric layer) from the opposing end (or perimeter) of the etched region to the first metal layer 635a, which forms a portion of the first busbar as described above. More generally, the distance between the ends of the fingertips of the IDT fingers to the beginning of the etch hole (i.e., a first edge of the etched region) is less than the spacing between the etch hole (i.e., a second edge of the etched region) and the opposing busbar. Thus, in this aspect, the distance D1 in the first direction that between the tip of the at least one finger (e.g., finger 636b) and an edge of the etched region 650 that is adjacent to the tip of the finger is less than the distance D2 in the first direction between a side surface of the first busbar (e.g., metal layer 635a) and an edge of the etched region that is adjacent to first busbar. As a result, the width (also denoted D1) of the filler material 660a in the first direction is less than the width (also denoted D2) of the filler material 660b. This configuration is further provided to reduce loss of the acoustic resonator during operation.

According to the exemplary aspects shown in FIGS. 6A and 6B, the etched regions 650 of the exemplary aspect achieves an improved Q factor by reducing acoustic leakage in the BE gap while also provided no mechanical issues since the piezoelectric layer 610 is otherwise solidly mounted to the Bragg stack (including layers 640a to 640d). Additionally, fabrication of the etched region 650 is achieved without etching through the metal layer 635a of the IDT. Moreover, the etching process does not require precise timing control and constraints. As a result, the depth of the etched region 650 may be different in exemplary aspects. For example, the piezoelectric layer 610 may only be partially removed such that the etched region includes a thinner layer of piezoelectric material than the piezoelectric layer 610 outside the etched region. In other exemplary aspects, the piezoelectric layer 610 may be fully removed without removal of any other layers. In yet other exemplary aspects, the Bragg stack may be fully removed in the etched region, with or without partial removal of the underlying substrate. As described herein with respect to FIGS. 6B, 7B, and 8B, the depth of the etched region is measured vertically (i.e., in the Z axis direction) in these figures, in a direction perpendicular to the planar dimension of the piezoelectric layer 610.

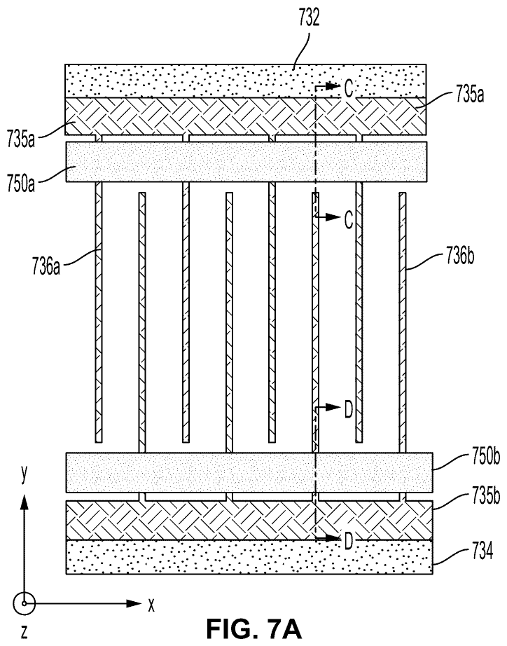

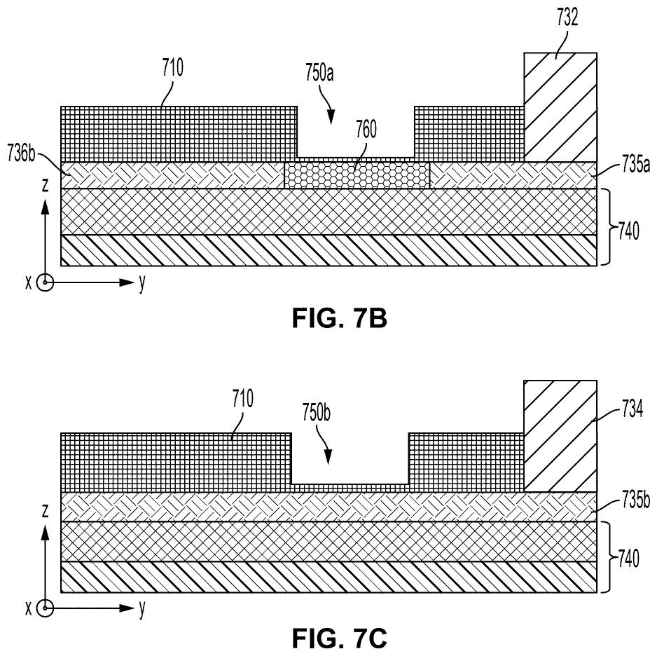

FIGS. 7A, 7B and 7C show another exemplary aspect of an etched region in the BE gap. Similarly, to FIG. 6A, the plan view of FIG. 7A does not show the piezoelectric layer in order to illustrate the positioning of the etched regions 750a and 750b (which are etched trenches) with respect to the conductor pattern. Similar to the configuration of FIG. 6A, first metal layer 735a and second metal layer 732 corresponds to busbar 132 of FIG. 1. Similarly, second metal layer 735b and second metal layer 734 corresponds to busbar 134 of FIG. 1. As will be described with respect to FIGS. 7B and 7C, a piezoelectric layer 710 is disposed on at least the conductor pattern that forms the interleaved fingers 736a and 736b and metal layers 735a and 735b (or a portion thereof), such that the conductor pattern is between the piezoelectric layer 710 and a Bragg stack 740. In an alternative aspect, the conductor pattern could be disposed on the top surface of the piezoelectric layer.

As shown in the plan view of FIG. 7A, the etched regions includes etched trenches 750a and 750b that extend horizontally (in a second direction, the X axis direction, substantially parallel with the busbars and perpendicular to the extension (e.g., first) direction of the fingers 736a and 736b) in the areas between the busbars (at the top and bottom of FIG. 7A) and the tips of the fingers, which extend from metal layers 735a and 735b, respectively. According to the exemplary aspects, the first trench 750a and the second trench 750b extend partially into the piezoelectric layer 710 in a thickness direction that is measured substantially perpendicular (i.e., in the Z axis direction) to a planar dimension (i.e., a plane in the X-Y plane) of the piezoelectric layer 710. As also shown in FIG. 7A, the first trench 750a is over at least a portion of the plurality of interleaved fingers 736a extending from the metal pattern 735a forming the first busbar. Similarly, the first trench 750b is over at least a portion of the plurality of interleaved fingers 736b extending from the metal pattern 735b forming the second busbar. Thus, as shown in FIGS. 7B and 7C, a thickness of the piezoelectric layer 710 is smaller in the first trench 750a and the second trench 750a than a thickness of the piezoelectric layer 710 outside of the first trench 750a and the second trench 750b.

As further shown, the top trench in FIG. 7A passes in the area between the top busbar and the tips of the fingers extending from the bottom busbar, and the bottom trench in FIG. 7A passes in the area between the top busbar and the tips of the fingers extending from the top busbar. Unlike the exemplary aspect of FIG. 6A, the etched region trenches of FIG. 7A pass across the metal fingers of the IDT. Although FIG. 7A shows two trenches passing close to and parallel with both busbars, the number of trenches is not limited and may include more or fewer trenches.

FIG. 7B shows a cross-sectional view that corresponds to one of two dashed-line areas (i.e., Section C-C) in FIG. 7A. FIG. 7C shows another cross-sectional view that corresponds to the other of two dashed-line areas (i.e., Section D-DC) in FIG. 7A. Section C-C in FIG. 7B illustrates a cross section that passes through an area that does not include the first metal layer 735a of the first busbar, similar to the dashed-line area (i.e., Section B-B) and corresponding cross-sectional view of FIGS. 6A and 6B. In this aspect, the space between the busbar and the tip of the IDT fingers 636b can be filled with a filling material 760, such as a dielectric material like silicon oxide. That is, this filling material 760 can be a dielectric deposited in the BE gap (e.g., between the respective tips of the interleaved fingers and the busbar) to provide a mechanical support for the piezoelectric layer 710 when it is deposited during manufacturing.

Unlike the exemplary aspect of FIGS. 6A and 6B, however, the depth (i.e., the thickness) of the etched regions 750a and 750b in the exemplary aspect of FIGS. 7A to 7C is shallower and extends only partially into the piezoelectric layer 710. That is, in this exemplary aspect, the piezoelectric layer 710 is partially removed in the etched regions 750a and 750b, with some piezoelectric material remaining within the etched regions 750a and 750b. Retaining a portion of the piezoelectric material in the etched regions 750a and 750b avoids damage to the metal IDT layer in this exemplary aspect because the trenches 750a and 750b (e.g., as shown in FIG. 7C) pass over the conductor pattern of the IDT.

The cross-sectional view of FIG. 7C runs parallel with one of the metal IDT fingers 736b. Because the etched region 750b is not as deep as, for example, as the etched regions 650 of the exemplary aspects of FIGS. 6A and 6B, the depth of the etched region 750b does not reach the metal layer 735b and/or IDT finger 736b and some piezoelectric material is left atop the conductor pattern to avoid damage thereto. For example, the etched regions 750a and 750b may include removal of 60% to 80% of the piezoelectric layer 710, leaving the rest at the bottom of the etched regions 750a and 750b.

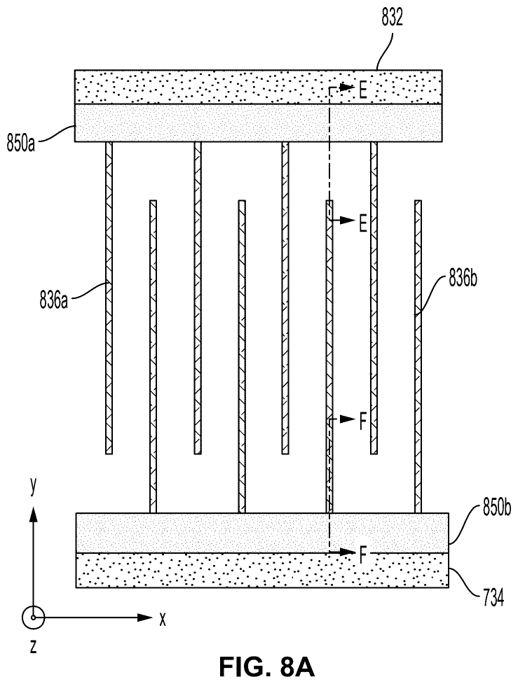

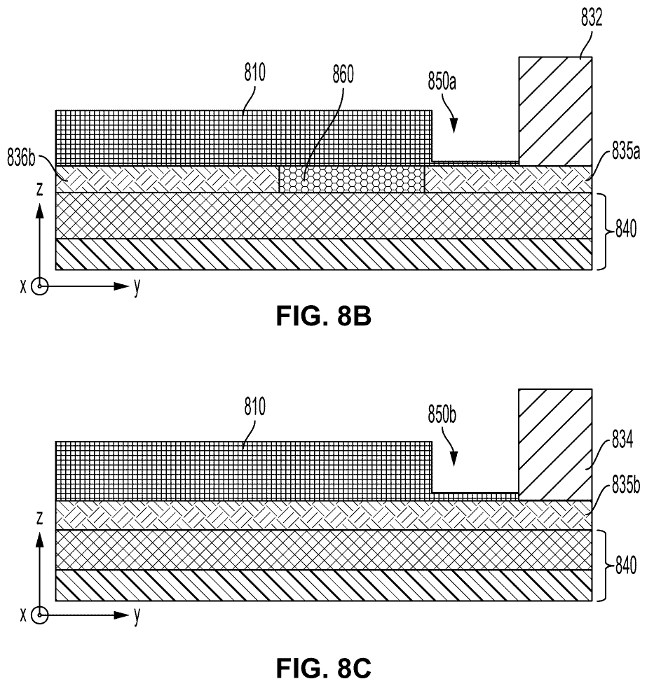

FIGS. 8A, 8B and 8C show another exemplary etched region configuration, in which the etched regions 850a and 850b (which are etched trenches) are located in the second metal layer of the busbar area. As shown in FIGS. 6A and 7A, FIG. 8A does not show the piezoelectric layer in order to illustrate the positional relationship between the etched region and the metal IDT layer. Otherwise, similar to the above configurations, first metal layer 835a and second metal layer 832 corresponds to busbar 132 of FIG. 1. Similarly, second metal layer 835b and second metal layer 834 corresponds to busbar 134 of FIG. 1. As will be described with respect to FIGS. 8B and 8C, a piezoelectric layer 810 is disposed on at least the conductor pattern that forms the interleaved fingers 836a and 836b and metal layers 835a and 835b (or a portion thereof), such that the conductor pattern is between the piezoelectric layer 810 and a Bragg stack 840. In an alternative aspect, the conductor pattern could be disposed on the top surface of the piezoelectric layer.

In the exemplary aspect of FIG. 8A, the etched regions 850a and 850b are positioned closer to the second metal layers 832 and 834 and outside of the area of the fingers 836a and 936b of the IDT. The etched regions 850a and 850b in the exemplary aspect of FIG. 8A are trenches extending substantially parallel with the busbars and perpendicular to the extension direction of the fingers of the IDT, similar to the aspect of FIG. 7A.

The top trench 850a in FIG. 8A passes near the metal layer 832 of the top busbar area and the bottom trench 850b in FIG. 8A passes near the metal layer 834 of the bottom busbar area, where neither trench overlaps the metal fingers 836a or 836b of the IDT. Although FIG. 8A shows two trenches 850a and 850b passing close to and substantially parallel with the first and second busbars, respectively, the number of trenches is not limited and may include more or fewer trenches. Furthermore, the position of the etched regions 850a and 850b are not limited to the configuration shown in FIGS. 8A to 8C. For example, the etched regions 850a and 850b may be in the busbar regions without being directly adjacent to the busbar. Additionally or alternatively, the etched regions 850a and 850b may partially overlap the metal fingers of the IDT.

FIGS. 8B and 8C shows two cross-sectional views, each corresponding to one of the two dashed lines (Sections E-E and F-F) in FIG. 8A. Similar to the cross-sectional views of FIGS. 6B, 7B and 7C, the cross-sectional views of FIGS. 8B and 8C are partial, as they do not show the substrate supporting the Bragg stack 840 and may not show the full Bragg stack, which may include more alternating layers than shown. As shown in FIGS. 8B and 8C, the etched regions 850a and 850b are positioned adjacent to the second metal layers 832 and 834 of the first and second busbars, such that one of the sidewalls of the etched region is defined by these second metal layers 832 and 834.

As noted above, the position of the etched regions 850a and 850b is not limited to the exemplary aspect shown in FIGS. 8B and 8C and these trenches may be in the busbar region without being directly adjacent to the busbar (i.e., without using the busbar as a sidewall). The cross-sectional view of FIG. 8B is similar to the cross-sectional view of FIG. 7B in that it shows a tip of one of the IDT fingers 836b and a filling material 860 (e.g., a dielectric such as silicon oxide) area where no metal layer exists beyond the tip of the IDT finger. As described above, the filling material 860 provides mechanical support for the piezoelectric layer (not shown) during the manufacturing process. Unlike the exemplary aspect of FIG. 7B, the position of the etched region in the aspect of FIG. 8B is farther from the tip of the IDT finger 836b and closer to the second metal layer 832 of the first busbar.

The same comparison applies to the cross-sectional view of FIG. 8C, which is similar to the cross-sectional view of FIG. 7C with a position of the etched region 850b closer to the second metal layer 734 of the second busbar. As in the exemplary aspect of FIGS. 7A to 7C, the depth of the etched regions 850a and 850b is such that some piezoelectric material remains at the bottom of the etched regions to protect the IDT metal layer from damage. That is, the piezoelectric layer 810 is partially etched in the exemplary aspect of FIGS. 8A to 8C.

The exemplary aspects of FIGS. 6A, 6B, 7A-7C, and 8A-8C may be combined in any one of various suitable ways, with respect to location, shape, and number of etched regions. The specific etched region configuration that would optimize Q for a particular SM XBAR structure may be based on the material and cut of the piezoelectric material (e.g., 120Y lithium niobate, 120Y lithium tantalate, 82Y, etc.), among other factors.

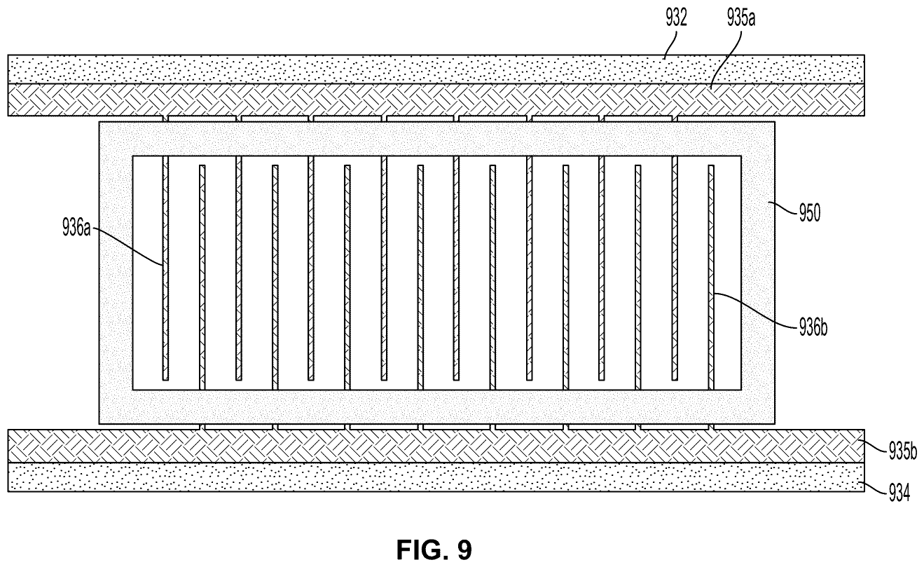

In the case that the etched region includes two trenches, as shown in the aspects of FIGS. 7A-7C and 8A-8C, the two trenches may be connected to each other at the edges of the IDT, as shown in FIG. 9. Similar to the above configurations, FIG. 9 illustrates that first metal layer 935a and second metal layer 932 corresponds to busbar 132 of FIG. 1. Similarly, second metal layer 935b and second metal layer 934 corresponds to busbar 134 of FIG. 1. Moreover, a piezoelectric layer (not shown) can be disposed on at least the conductor pattern that forms the interleaved fingers 936a and 936b and metal layers 935a and 935b (or a portion thereof), such that the conductor pattern is between the piezoelectric layer and a Bragg stack.

According to this exemplary aspect, connecting trenches may be formed on either side of the interleaved fingers of the IDT to effective form a continuous (e.g., rectangular shaped) trench 950. In FIG. 9, the connecting trenches run vertically, parallel with the extension direction of the IDT fingers, and connect the ends of the two trenches (e.g., the top and bottom trenches in FIGS. 7A and 8A) to each other. As a result, the plurality of interleaved fingers of the IDT (e.g., fingers 936a and 936b) are disposed between the two connecting trenches of the etched region 950 in a plan view of the piezoelectric layer.

Although trench 950 is shown as a rectangular in an exemplary aspect, the shape of this continuously etched region is not so limited and can be an oval or a rectangle with curved corners in alternative aspects.

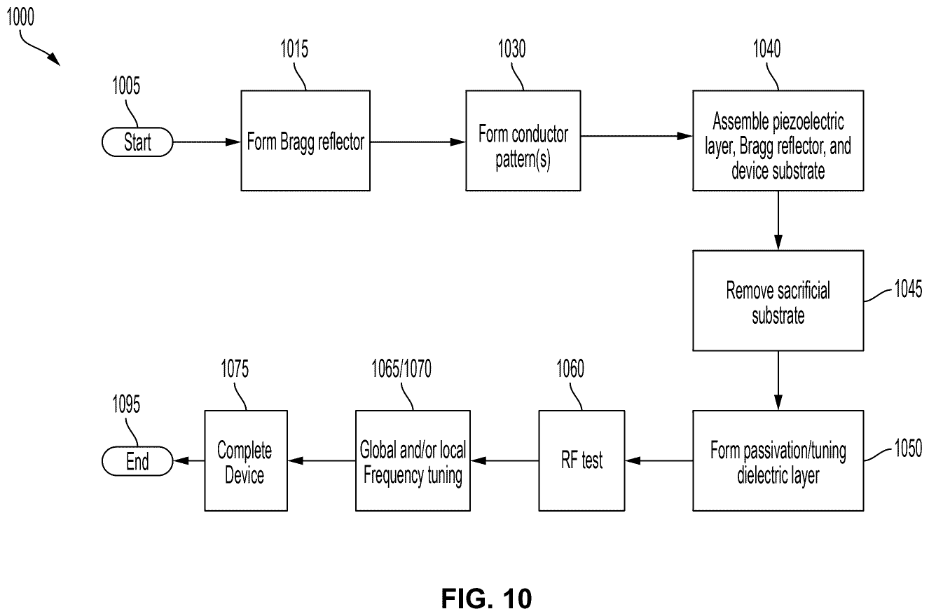

FIG. 10 is a simplified flow chart summarizing a process 1000 for manufacturing a filter device incorporating XBARs according to an exemplary aspect. It should be appreciated that while FIG. 10 generally describes a process for fabricating a single filter device, multiple filter devices may be fabricated simultaneously on a common wafer (consisting of a piezoelectric layer bonded to a substrate). In this case, each step of the process 1000 may be performed concurrently on all of the filter devices on the wafer.

As shown, the process 1000 is for fabricating a filter device including multiple XBARs, such as the SM XBARs having an etched region described above, for example in reference to FIGS. 6A-9. The process 1000 starts at 1005 with a device substrate and a thin layer of piezoelectric material disposed on a sacrificial substrate. The process 1000 ends at 1095 with a completed filter device. It is noted that the flow chart of FIG. 10 includes only major process steps. Various conventional process steps (e.g., surface preparation, cleaning, inspection, baking, annealing, monitoring, testing, etc.) may be performed before, between, after, and during the steps shown in FIG. 10.

At 1015 an acoustic Bragg reflector (or Bragg stack) is formed by depositing alternating layers of high acoustic impedance and low acoustic impedance materials on a substrate. Each of the layers has a thickness equal to or about one-fourth of the acoustic wavelength. Materials having comparatively low acoustic impedance include silicon dioxide, silicon oxycarbide, aluminum, and certain plastics such as cross-linked polyphenylene polymers. Materials having comparatively high acoustic impedance include silicon nitride, aluminum nitride, and metals such as molybdenum, tungsten, gold, and platinum. All of the high acoustic impedance layers are not necessarily the same material, and all of the low acoustic impedance layers are not necessarily the same material. The total number of layers in the acoustic Bragg reflector may be from about five to more than twenty. However, fewer or more alternating layers may be used to form the Bragg stack.

At 1015, all of the layers of the acoustic Bragg reflector may be deposited on a surface of a device substrate. Alternatively, some of the layers of the acoustic Bragg reflector may be deposited on a surface of the device substrate and the remaining layers are later deposited on the conductor pattern formed on a surface of the piezoelectric plate.

A first conductor pattern, including IDTs of each XBAR, is formed at 1030 by depositing and patterning one or more conductor layers on the back side of the piezoelectric layer, as described with reference to FIGS. 6B, 7B/7C, and 8B/8C. The conductor layer (e.g., the first metal layer as described herein) may be, for example, aluminum, an aluminum alloy, copper, a copper alloy, or some other conductive metal. In some aspects, one or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern (e.g., the second metal layer as described herein) of gold, aluminum, copper or other higher conductivity metal may be formed over portions of the first conductor pattern (for example the IDT bus bars and interconnections between the IDTs).

Each conductor pattern may be formed at 1030 by depositing the conductor layer and, in some aspects, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 1030 using a lift-off process. Photoresist may be deposited over the piezoelectric layer and patterned to define the conductor pattern. Moreover, the conductor layer and, in some aspects, one or more other layers may be deposited in sequence over the surface of the piezoelectric layer. The photoresist may then be removed, which removes the excess material, leaving the conductor pattern. In an alternative aspect, formation of all or part of the Bragg reflector as described above at 1015 may be performed on the formed conductor pattern after 1030.

The piezoelectric layer may be, for example, a lithium niobate plate or a lithium tantalate plate, either of which may be Z-cut, rotated Z-cut, Y-cut, rotated Y-cut, or rotated YX-cut. For historical reasons, a rotated Y-cut plate configuration may be commonly referred to as “Y-cut”, where the “cut angle” is the angle between the y axis and the normal to the plate. The “cut angle” is equal to β+90°. For example, a plate with Euler angles [0°, 30°, 0°] is commonly referred to as “120° rotated Y-cut”. In some embodiments, the piezoelectric layer's z axis may be normal to the plate surface and the y axis orthogonal to the IDT fingers. Such piezoelectric plates have Euler angles of 0, 0, 90°. Further embodiments may include a piezoelectric layer with Euler angles θ, β, 90°, where B is in the range from −15° to +5°, 0≤β≤60, or any combination thereof. The piezoelectric layer may be some other material and/or some other cut. The device substrate may preferably be silicon. The device substrate may be some other material that allows formation of deep cavities by etching or other processing.

At 1040, the piezoelectric layer is deposited over the conductor pattern of the IDT and the Bragg reflector. The piezoelectric layer may be bonded by a wafer bonding process. One or more layers of intermediate materials, such as an oxide, may be formed or deposited on the mating surface of one or both of the piezoelectric layer and the Bragg stack. For example, high acoustic impedance and low acoustic impedance layers of the Bragg stack may be formed or deposited on the mating surface of one or both of the piezoelectric layer and device substrate. Additionally, the conductor patterns formed at 1030 are deposited on a surface of the piezoelectric layer facing the device substrate and the Bragg stack. One or both mating surfaces may be activated using, for example, a plasma process. The mating surfaces may then be pressed together with considerable force to establish molecular bonds between the piezoelectric layer and the device substrate or intermediate material layers.

At 1045, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 1045, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached. For example, the etched regions described above with reference to FIGS. 6A-9 may be formed by etching the piezoelectric layer, with or without etching the IDT metal layer, the Bragg stack, or the device substrate.

Thin layers of single-crystal piezoelectric materials laminated to a non-piezoelectric substrate are commercially available. At the time of this application, both lithium niobate and lithium tantalate layers are available bonded to various substrates including silicon, quartz, and fused silica. Thin layers of other piezoelectric materials may be available now or in the future. The thickness of the piezoelectric layer may be between 300 nm and 1000 nm. When the substrate is silicon, a layer of SiO₂ may be disposed between the piezoelectric layer and the substrate. When a commercially available piezoelectric layer/device substrate laminate is used, certain steps may be omitted in an exemplary aspect.

At 1050, a passivation/tuning dielectric layer may be deposited over the piezoelectric layer. The passivation/tuning dielectric layer may cover the entire surface of the filter except for pads for electrical connections to circuitry external to the filter. In some instantiations of the process 1000, the passivation/tuning dielectric layer may be formed on the conductor patterns formed in 1030, before bonding to the device substrate.

Ideally, most or all of the filter devices on a wafer will meet a set of performance requirements. However, normal process tolerances will result in variations in parameters such as the thicknesses of dielectric layer formed at 1050, variations in the thickness and line widths of conductors and IDT fingers formed at 1030, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 1050. The frequency of a filter device passband can be lowered by adding material to the passivation/tuning layer, and the frequency of the filter device passband can be increased by removing material to the passivation/tuning layer. Typically, the process 1000 is biased to produce filter devices with passbands that are initially lower than a required frequency range but can be tuned to the desired frequency range by removing material from the surface of the passivation/tuning layer.

At 1060, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 1065, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 1060 may be processed to generate a global contour map indicating the amount of material to be removed as a function of two-dimensional position on the wafer. The material is then removed in accordance with the contour map using the selective material removal tool.

At 1070, local frequency tuning may be performed in addition to, or instead of, the global frequency tuning performed at 1065. “Local” frequency tuning is performed with a spatial resolution smaller than an individual filter device. The test results from 1060 may be processed to generate a map indicating the amount of material to be removed at each filter device. Local frequency tuning may require the use of a mask to restrict the size of the areas from which material is removed. For example, a first mask may be used to restrict tuning to only shunt resonators, and a second mask may be subsequently used to restrict tuning to only series resonators (or vice versa). This would allow independent tuning of the lower band edge (by tuning shunt resonators) and upper band edge (by tuning series resonators) of the filter devices.

After frequency tuning at 1065 and/or 1070, the filter device is completed at 1075. Actions that may occur at 1075 include forming the staggered inductance configuration, forming bonding pads or solder bumps or other means for making connection between the device and external circuitry (if such pads were not formed at 1030); excising individual filter devices from a wafer containing multiple filter devices; other packaging steps; and additional testing. After each filter device is completed, the process ends at 1095.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator comprising:
a substrate;
a piezoelectric layer;
a Bragg reflector layer disposed between the substrate and the piezoelectric layer; and
an interdigital transducer (IDT) at a surface of the piezoelectric layer that faces the Bragg reflector layer, the IDT including a plurality of interleaved fingers extending from a first busbar and a second busbar,
wherein at least one etched region extends into at least a portion of the piezoelectric layer, the at least one etched region including an area between the first busbar and a tip of at least one finger of the plurality of interleaved fingers extending from the second busbar.

2. The acoustic resonator of claim 1, wherein two adjacent fingers of the plurality of interleaved fingers extend from the first direction and the at least one etched region is located between the two adjacent fingers relative to a direction that is substantially perpendicular to a direction in which the fingers extend.

3. The acoustic resonator of claim 1, wherein the at least one etched region comprises a plurality of first etched regions, each of the plurality of etched regions being located (i) between a different set of adjacent fingers extending from the first busbar, and (ii) between the first busbar and a tip of a corresponding finger of the plurality of interleaved fingers extending from the second busbar.

4. The acoustic resonator of claim 3, further comprising a plurality of second etched regions extending in at least a portion of the piezoelectric layer, each of the plurality of second etched regions being located (i) between the second busbar and a tip of a corresponding finger of the plurality of interleaved fingers extending from the first busbar, and (ii) between a different set of adjacent fingers extending from the second busbar.

5. The acoustic resonator of claim 1, wherein the at least one etched region includes a first trench extending in a direction substantially perpendicular to a direction in which the plurality of interleaved fingers of the IDT extend, the first trench being located between the first busbar and tips of the plurality of interleaved fingers extending from the second busbar and being disposed over the plurality of interleaved fingers extending from the first busbar.

6. The acoustic resonator of claim 5, wherein the at least one etched region includes a second trench extending in the direction substantially perpendicular to the direction in which the plurality of interleaved fingers of the IDT extend, the second trench being located between the second busbar and tips of the plurality of interleaved fingers extending from the first busbar and being disposed over the plurality of interleaved fingers extending from the second busbar.

7. The acoustic resonator of claim 6, wherein the first trench and the second trench extend partially into the piezoelectric layer in a thickness direction measured substantially perpendicular to a surface of the piezoelectric layer, such that a thickness of the piezoelectric layer is smaller in the first trench and the second trench than a thickness of the piezoelectric layer outside of the first trench and the second trench.

8. The acoustic resonator of claim 6, wherein the first trench and the second trench are connected to each other by two connecting trenches extending, such that the plurality of interleaved fingers of the IDT are disposed between the two connecting trenches in a plan view of the piezoelectric layer.

9. The acoustic resonator of claim 1, wherein the at least one etched region is directly adjacent to the first busbar, such that the first busbar defines a sidewall of the at least one etched region.

10. The acoustic resonator of claim 1, wherein the at least one etched region extends partially into the piezoelectric layer in a thickness direction measured substantially perpendicular to a surface of the piezoelectric layer, such that a thickness of the piezoelectric layer is smaller in the at least one etched region than a thickness of the piezoelectric layer outside of the at least one etched region.

11. The acoustic resonator of claim 1, wherein the at least one etched region extends fully through the piezoelectric layer.

12. The acoustic resonator of claim 11, wherein the Bragg reflector layer is partially removed in the at least one etched region, such that a thickness of the Bragg reflector layer is smaller in the at least one etched region than a thickness of the Bragg reflector layer outside of the at least one etched region.

13. The acoustic resonator of claim 11, wherein a distance D1 between the tip of the at least one finger and an edge of the at least one etched region that is adjacent to the tip is less than a distance D2 between a side surface of the first busbar and an edge of the at least one etched region that is adjacent to the first busbar, the distances D1 and D2 being measured in a direction parallel to a plan view of the piezoelectric layer.

14. A filter device comprising:
a plurality of bulk acoustic resonators each including:
a substrate;
a piezoelectric layer;
at least one Bragg reflector layer disposed between the substrate and the piezoelectric layer; and
an interdigital transducer (IDT) at a surface of the piezoelectric layer, the IDT including a plurality of interleaved fingers extending from first and second busbars,
wherein at least one bulk acoustic resonator of the plurality of bulk acoustic resonators includes at least one etched region where a portion of the piezoelectric layer is removed, and
wherein the at least one etched region includes an area between a first busbar of the IDT and a tip of at least one finger of the plurality of interleaved fingers.

15. The filter device of claim 14, wherein the at least one etched region comprises a plurality of first etched regions where at least a portion of the piezoelectric layer is removed, each of the plurality of first etched regions being located (i) between a different set of adjacent fingers extending from the first busbar, and (ii) between the first busbar and a tip of a corresponding finger of the plurality of interleaved fingers extending from the second busbar.

16. The filter device of claim 15, wherein the at least one etched region further comprises a plurality of second etched regions where at least a portion of the piezoelectric layer is removed, each of the plurality of second etched regions being located (i) between the second busbar of the IDT and a tip of a corresponding finger of the plurality of interleaved fingers extending from the first busbar of the IDT, and (ii) between a different set of adjacent interleaved fingers extending from the second busbar of the IDT.

17. The filter device of claim 14, wherein the at least one etched region includes a first trench extending in a direction substantially perpendicular to a direction in which the plurality of interleaved fingers of the IDT extend, the first trench being located between the first busbar of the IDT and tips of the plurality of interleaved fingers extending from the second busbar of the IDT.

18. The filter device of claim 17, wherein the at least one etched region includes a second trench extending in the direction substantially perpendicular to the direction in which the plurality of interleaved fingers of the IDT extend, the second trench being located between the second busbar of the IDT and tips of the plurality of interleaved fingers extending from the first busbar of the IDT.

19. The filter device of claim 14, wherein the at least one etched region of the at least one bulk acoustic resonator extends fully through the piezoelectric layer.

20. A radio frequency module, comprising:
a filter device including a plurality of bulk acoustic resonators; and
a radio frequency circuit coupled to the filter device, the filter device and the radio frequency circuit being enclosed within a common package,
wherein at least one of the plurality of bulk acoustic resonators of the filter device includes:
a substrate;
a piezoelectric layer;
at least one Bragg reflector layer disposed between the substrate and the piezoelectric layer; and
an interdigital transducer (IDT) at a surface of the piezoelectric layer, the IDT including a plurality of interleaved fingers extending from first and second busbars,
wherein at least one bulk acoustic resonator of the plurality of bulk acoustic resonators includes at least one etched region where a portion of the piezoelectric layer is removed, the at least one etched region including an area between a first busbar of the IDT and a tip of at least one finger of the plurality of interleaved fingers that extends from a second busbar of the IDT.
